(19) United States
(12) Patent Application Publication
(10) Pub. No.: US 2013/0127308 A1
(43) Pub. Date: May 23, 2013

(54) MULTIFUNCTIONAL CASE FOR PORTABLE ELECTRONIC DEVICE

(71) Applicant: GANG YANG, Shenzhen City (CN)

(72) Inventor: GANG YANG, Shenzhen City (CN)

(73) Assignees: FIH (HONG KONG) LIMITED, Kowloon (HK); SHENZHEN FUTAIHONG PRECISION INDUSTRY CO., LTD., ShenZhen City (CN)

(21) Appl. No.: 13/405,951

(22) Filed: Feb. 27, 2012

(30) Foreign Application Priority Data
Nov. 18, 2011 (CN) 201110367874.7

(51) Int. Cl. H05K 5/02

(52) U.S. Cl. 312/223.1

(57) ABSTRACT

A multifunctional case includes a first housing defining two opposite sleeves and a second housing having two opposite shafts. Each shaft adjustably is received in one of the sleeves so the second housing is capable of rotate relative to the first housing between a first state and a second state. When the second housing is located in the first state, the second housing and the first housing are co-planar to form a receiving space for receiving an electronic device. When the second housing is located in the second state, the second housing is angled relative to the first housing to support the electronic device.

### BACKGROUND

1. Technical Field

The exemplary disclosure relates to cases for portable electronic devices, particularly, to a multifunction case for protecting and supporting portable electronic devices.

2. Description of Related Art

On one hand, cases are widely applied to protect portable electronic devices. On another hand, users generally need a holder for supporting the portable electronic device to read an eBook or watch video. However, it can be difficult to carry the case and the holder at the same time. In many cases, the holder can be easily left behind after use.

Therefore, there is room for improvement within the art.

### BRIEF DESCRIPTION OF THE DRAWINGS

Many aspects of the multifunctional case can be better understood with reference to the following drawings. The components in the drawings are not necessarily drawn to scale, the emphasis instead being placed upon clearly illustrating the principles of the multifunctional case.

FIG. 1 is an exploded view of a case according to an exemplary embodiment.

FIG. 2 is an enlarged view of the case in a circle of II.

FIG. 3 is an assembled view of the support device of FIG. 1 in a first state.

FIG. 4 is an assembled and partially enlarged view of the case of FIG. 1 in a second state.

FIG. 5 is a schematic view of the case of FIG. 3 where an electronic device is accommodated.

FIG. 6 is a schematic view of the case of FIG. 3 where an electronic device is accommodated.

### DETAILED DESCRIPTION

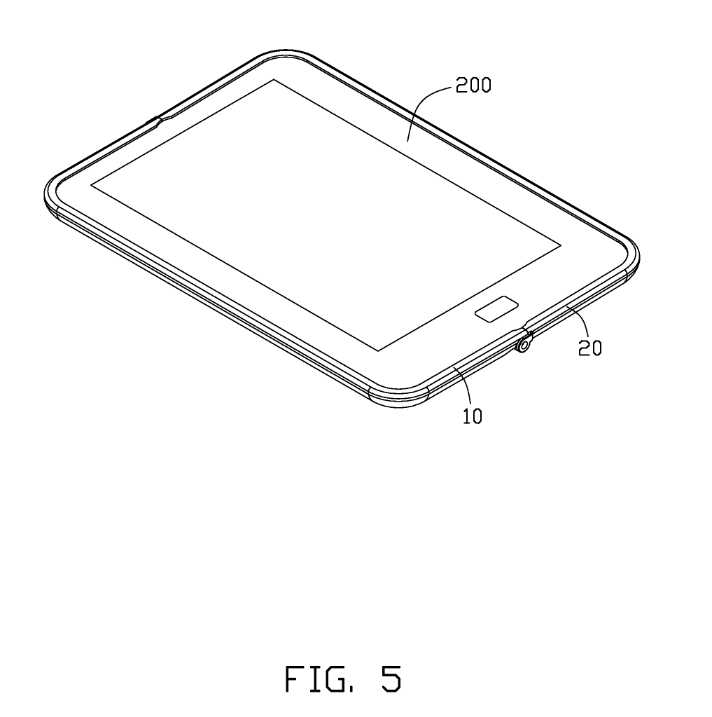

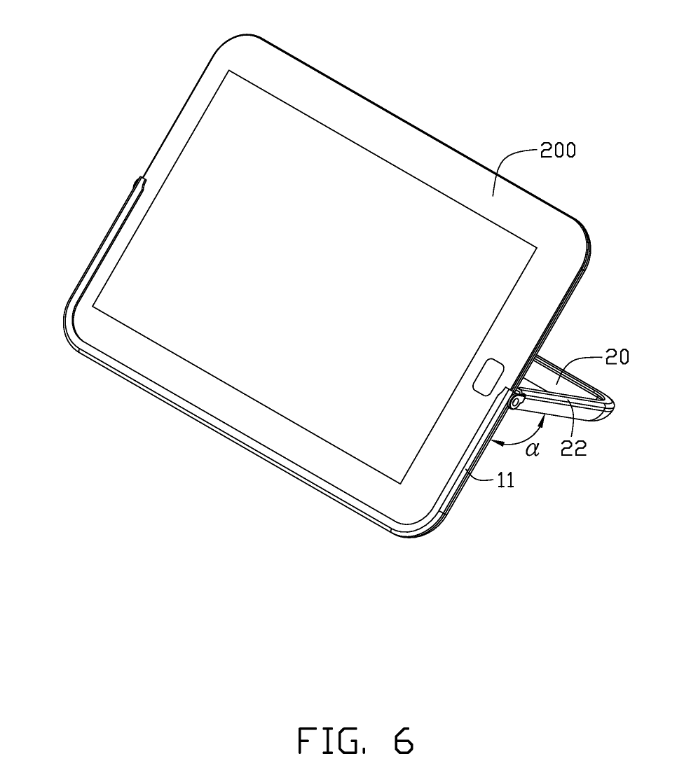

FIGS. 5 and 6 show an exemplary embodiment of a multifunctional case 100. The case 100 is selectively used to receive a portable electronic device 200 like shown in FIG. 5, or support the portable electronic device 200 like shown in FIG. 6.

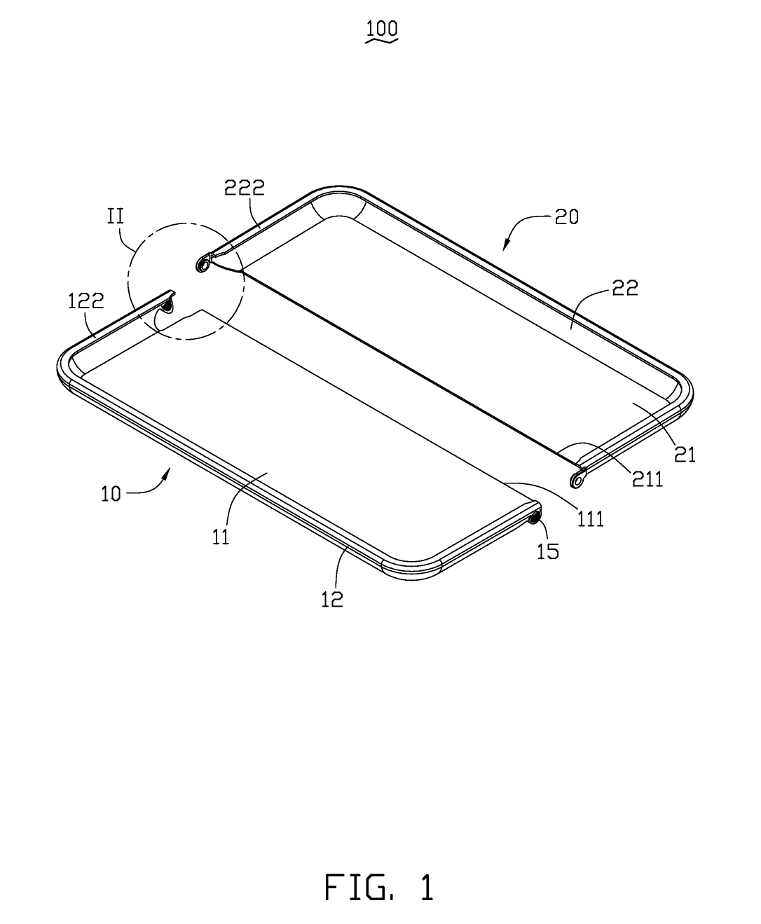

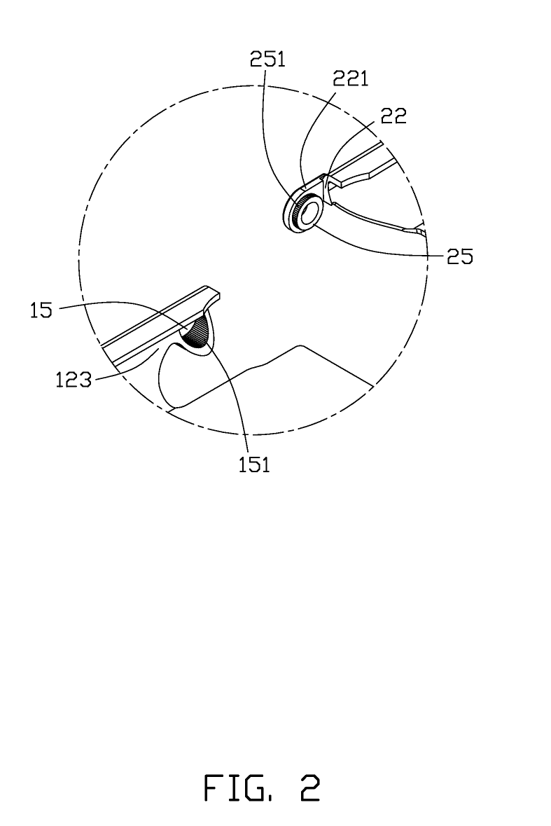

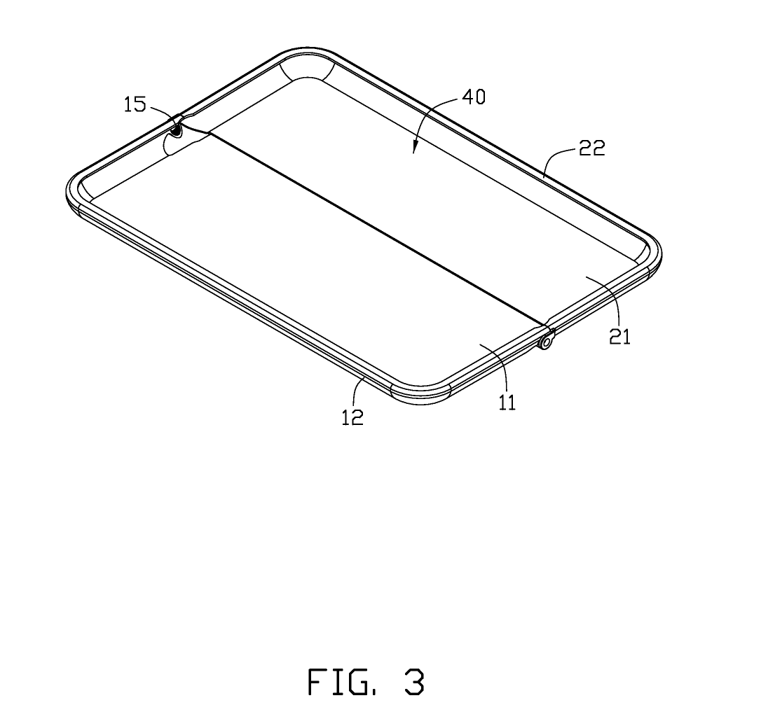

Referring to FIGS. 1 and 2, the case 100 includes a first housing 10 and a second housing 20. The first housing 10 includes two opposite sleeves 15, the second housing 20 includes two opposite shafts 25 which are rotatably received in the sleeves 15 so the second housing 20 can rotate relative to the first housing 10 along the shafts 25 between a first state (as shown in FIG. 3) and a second state (as shown in FIG. 6).

The first housing 10 includes a first main body 11 and a first sidewall 12. The first main body 11 includes a first joint edge 111 facing the second housing 20. The first sidewall 12 protrudes from an edge of the first main body 11 opposite to the first joint edge 111. A first latching plate 122 protrudes from a distal end of the first sidewall 12 opposite to the first main body 11. Two cantilevers 123 protrude from two opposite ends of the first sidewall 12. In this exemplary, each sleeve 15 is defined in one of the cantilevers 123, and each sleeve 15 has a plurality of ribs 151 longitudinally protruding from an inner surface of the sleeve 15.

The second housing 20 includes a second main body 21 and a second sidewall 22. The second main body 21 includes a second joint edge 211 facing the first housing 10. The second sidewall 22 protrudes from an edge of the second main body 21 opposite to the second joint edge 211. A second latching plate 222 protrudes from a distal end of the second sidewall 22 opposite to the second main body 21. Two blocks 221 protrude from two opposite ends of the second sidewall 22. In this exemplary, each shaft 25 protrudes from one of the second blocks 221, and each shaft 25 has a plurality of grooves 251 longitudinally defined in a peripheral surface of the shaft. The ribs 151 are releasably received in the grooves 251, to adjustably position the second housing 20 at any states between the first state and the second state.

Referring to FIGS. 1-3, in assembly, each shaft 25 is rotatably located in one of the sleeves 15 with the ribs 151 engaging the grooves 251. The second housing 20 rotates relative to the first housing 10 until the first joint edge 111 joints with the second joint edge 211 so the case 100 is positioned in the first state as shown FIG. 3. At this time, the first main body 11 and the second main body 21 are co-planar, and a receiving space 40 is cooperatively formed by the first main body 11, the second main body 21, the first sidewall 12, the second sidewall 22, the first latching plate 122 and the second latching plate 222.

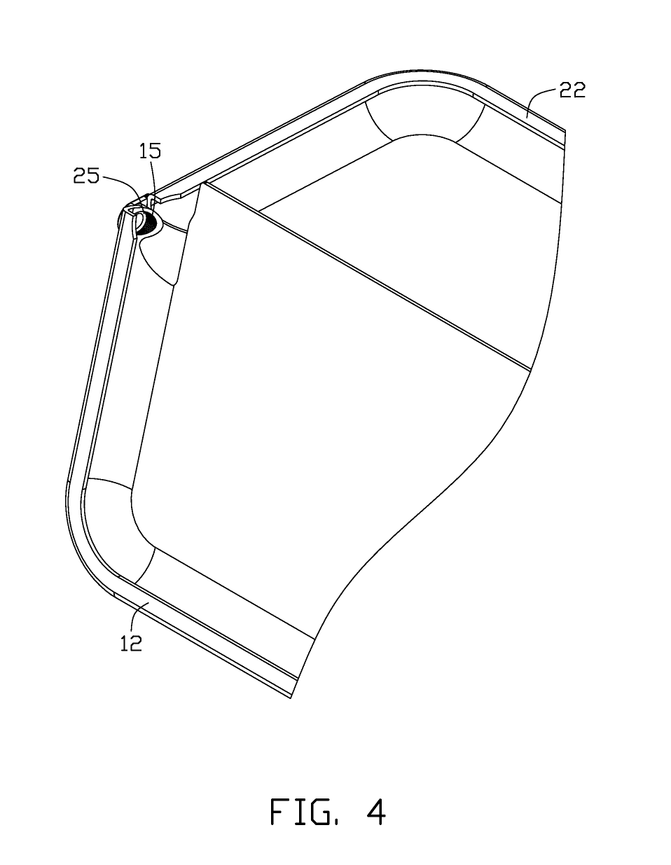

Referring to FIGS. 3-6, in use, the second housing 20 rotates relative to the first housing 10 from the first state (as shown in FIG. 3) to a predetermined state, such as, the second state (as shown in FIG. 4) wherein the first housing 10 angles with the second housing 20. The ribs 151 engage the grooves 251 making the second housing 20 firmly position in the second state. The electronic device 200 is inserted into the first housing 10. The second housing 20 rotates relative to the first housing 10 from the second state to the first state to form the receiving space 40 between the first housing 10 and the second housing 20 so the electronic device 200 is received in the receiving space 40 and protected by the case 100. Then, a user can rotate the shafts 25 relative to the sleeves 15, to adjust the angle a of the second housing 20 relative to the first housing 10 until the electronic device has a comfortable viewing angle, such as shown in FIG. 6.

Even though numerous characteristics and advantages of the present embodiments have been set forth in the foregoing description, together with details of structures and functions of various embodiments, the disclosure is illustrative only, and changes may be made in detail, especially in matters of shape, size, and arrangement of parts within the principles of the present disclosure to the full extent indicated by the broad general meaning of the terms in which the appended claims are expressed.

What is claimed is:

1. A multifunctional case, comprising:
a first housing having a first joint edge and two opposite sleeves; and
a second housing having a second joint edge and two opposite shafts, wherein each shaft is adjustably received in one of the sleeves to move the first joint surface away from the second joint surface.

2. The multifunctional case of claim 1, wherein the first housing includes a first main body and a first sidewall protruding from the first main body, two cantilever protrudes from two opposite ends of the first sidewall; each sleeve is defined in one of the cantilevers.

3. The multifunctional case of claim 2, wherein the second housing includes a second main body and a second sidewall protruding from the second main body, two blocks protrudes from the two opposite ends of the second sidewall, each shaft protrudes from one of the blocks.

4. The multifunctional case of claim 3, wherein the first sidewall protrudes from an edge of the first main body opposite to the first joint surface.

5. The multifunctional case of claim 4, wherein the second sidewall protrudes from an edge of the second main body opposite to the second joint surface.

6. The multifunctional case of claim 5, wherein a first latching plate protrudes from a distal end of the first sidewall, the first latching plate and the first main body are both located at one side of the first sidewall.

7. The multifunctional case of claim 6 wherein a second latching plate protrudes from a distal end of the second sidewall, the second latching plate and the second main body are both located at one side of the second sidewall.

8. The multifunctional case of claim 7, wherein a receiving space is cooperatively formed by the first main body, the second main body, the first sidewall, the second sidewall, the first latching plate and the second latching plate to receive a portable electronic device.

9. A multifunctional case, comprising:
a first housing defining two opposite sleeves; and
a second housing having two opposite shafts, each shaft adjustably received in one of the sleeves so the second housing being capable of rotate relative to the first housing between a first state and a second state;
wherein when the second housing is located in the first state, the second housing and the first housing are co-planar to form a receiving space for receiving an electronic device; when the second housing is located in the second state, the second housing is angled relative to the first housing to support the electronic device.

10. The multifunctional case of claim 9, wherein a plurality of ribs protrude from an inner surface of each sleeve; a plurality of grooves defined in a peripheral surface of each shaft, in which the ribs are releasably received to position the second housing in any states between the first state and the second state.

11. The multifunctional case of claim 10, wherein the first housing includes a first main body and a first sidewall protruding from the first main body, two cantilever protrudes from two opposite ends of the first sidewall; each sleeve is defined in one of the cantilevers.

12. The multifunctional case of claim 11, wherein the second housing includes a second main body and a second sidewall protruding from the second main body, two blocks protrudes from the two opposite ends of the second sidewall, each shaft protrudes from one of the blocks.

13. The multifunctional case of claim 12, wherein the first housing includes a first joint edge, the second housing includes a second joint edge jointing with the first joint edge when the second housing is located in the first state.

14. The multifunctional case of claim 13, wherein the first sidewall protrudes from an edge of the first main body opposite to the first joint surface.

15. The multifunctional case of claim 13, wherein the second sidewall protrudes from an edge of the second main body opposite to the second joint surface.

16. The multifunctional case of claim 13, wherein a first latching plate protrudes from a distal end of the first sidewall, the first latching plate and the first main body are both located at one side of the first sidewall.

17. The multifunctional case of claim 16, wherein a second latching plate protrudes from a distal end of the second sidewall, the second latching plate and the second main body are both located at one side of the second sidewall.

18. The multifunctional case of claim 17, wherein the receiving space is cooperatively formed by the first main body, the second main body, the first sidewall, the second sidewall, the first latching plate and the second latching plate.

19. A multifunctional case, comprising:
a first housing having two opposite sleeves; and
a second housing having two opposite shafts, wherein each shaft is adjustably received in one of the sleeves to adjust an angle between first housing and the second housing such that the second housing is capable of coplanar with the first housing to form a receiving space to receive an electronic device or is capable of angling with the first housing to support the electronic device.

20. The multifunctional case of claim 19, wherein the first housing includes a first main body and a first sidewall protruding from the first main body, two cantilever protrudes from two opposite ends of the first sidewall; each sleeve is defined in one of the cantilevers.
